(19) United States
(12) Patent Application Publication
(10) Pub. No.: US 2026/0343078 A1
(43) Pub. Date: Oct. 29, 2026

(54) LENS DRIVING DEVICE, CAMERA DEVICE, AND OPTICAL DEVICE

(71) Applicant: LG INNOTEK CO., LTD., Seoul (KR)

(72) Inventor: Sang Yeon HAN, Seoul (KR)

(21) Appl. No.: 19/157,622

(22) PCT Filed: Jan. 10, 2024
(86) PCT No.: PCT/KR2024/000506

§ 371 Date: Aug. 18, 2025

(30) Foreign Application Priority Data
Feb. 17, 2023 (KR) 10-2023-0021482

(51) Int. Cl. H04N 23/54; G01R 33/07; G03B 5/04; H04N 23/55; H04N 23/57

(52) U.S. Cl. CPC H04N 23/54; G01R 33/072; G03B 5/04; H04N 23/55; H04N 23/57; G03B 2205/0015; G03B 2205/0069

(57) ABSTRACT

A lens driving device, according to an embodiment of the present invention, comprises: a fixed unit; a first moving unit disposed on the fixed unit; a second moving unit disposed within the first moving unit; a first driving unit for moving the first moving unit in the optical axis direction; and a second driving unit for moving the second moving unit in a first direction perpendicular to the optical axis direction, wherein the second driving unit comprises a second magnet disposed on the second moving unit; and a second coil and a second sensor disposed on the fixed unit, the second sensor comprises two sensors spaced apart in the first direction within the second coil, and at least one of the two sensors overlaps the second magnet in a second direction perpendicular to the optical axis direction and the first direction.

### TECHNICAL FIELDS

The teachings in accordance with exemplary and non-limiting embodiments of the present invention relate generally to a lens driving device, a camera device, and an optical instrument.

### BACKGROUND ARTS OF THE INVENTION

Ultra-compact, low-power camera modules are difficult to implement using the voice coil motor (VCM) technology employed in conventional camera modules, prompting active research in this area.

In camera modules installed in small electronic devices such as smartphones, the camera module may frequently be subjected to shocks during use, and may also vibrate slightly due to factors such as user hand shake during filming. Considering these factors, recent developments have focused on adding anti-vibration mechanisms to camera modules.

### SUMMARY OF THE INVENTION

### Technical Subjects

The present embodiment is intended to provide a lens driving device that can precisely sense the position of a moving unit during movement of the moving unit for hand shake correction.

### Technical Solution

In order to solve the abovementioned technical subjects, a lens driving device, according to an embodiment of the present invention, may comprise: a fixed unit; a first moving unit disposed on the fixed unit; a second moving unit disposed within the first moving unit; a first driving unit for moving the first moving unit in the optical axis direction; and a second driving unit for moving the second moving unit in a first direction perpendicular to the optical axis direction, wherein the second driving unit comprises a second magnet disposed on the second moving unit; and a second coil and a second sensor disposed on the fixed unit, the second sensor comprises two sensors spaced apart in the first direction within the second coil, and at least one of the two sensors overlaps the second magnet in a second direction perpendicular to the optical axis direction and the first direction.

Preferably, but not necessarily, the length of the second magnet may be longer than the distance between the two sensors of the second sensor.

Preferably, but not necessarily, when the second moving unit is moved to its maximum position in the first direction, one of the second sensors may overlap with the second magnet in the second direction, while the others may not overlap with the second magnet in the second direction.

Preferably, but not necessarily, the second coil may include two coils disposed by being spaced apart from each other in the first direction, and the second sensor may include two sensors disposed inside each of the two coils.

Preferably, but not necessarily, the length of the second magnet in the first direction may be shorter than the length of the second coil in the first direction.

Preferably, but not necessarily, the lens driving device may further comprise a substrate disposed on the side of the fixed unit, and the second coil and the second sensor may be disposed on the substrate, and the second coil and the second sensor may overlap with the substrate in the second direction.

The lens driving device may further comprise a third driving unit for moving the second moving unit in the second direction, and the third driving unit may include a third magnet disposed on the second moving unit, a third coil and a third sensor disposed on the fixed unit, wherein the third sensor may include two sensors disposed in the third coil and spaced apart in the second direction, and at least one of the two sensors of the third sensor may overlap with the third magnet in the first direction.

To solve the above technical problems, a lens driving device, according to an embodiment of the present invention, may comprise: a fixed unit; a first moving unit disposed on the fixed unit; a second moving unit disposed within the first moving unit; a first driving unit for moving the first moving unit in the optical axis direction; and a second driving unit for moving the second moving unit in a direction perpendicular to the optical axis direction, wherein the second driving unit may include a second magnet and a third magnet disposed on the second moving unit, a second coil and a third coil disposed on the fixed unit, a second sensor disposed within the second coil, and a third sensor disposed within the third coil, wherein the second sensor may include two sensors spaced apart within the second coil, and the third sensor may include two sensors spaced apart within the third coil.

Preferably, but not necessarily, the two sensors of the second sensor may be spaced apart in the first direction, the two sensors of the third sensor may be spaced apart in the second direction, and the second moving unit may move in the second direction by the second magnet and the second coil and move in the first direction by the third magnet and the third coil.

To solve the above technical problems, a lens driving device, according to an embodiment of the present invention, may comprise: a fixed unit; a first moving unit disposed on the fixed unit; a second moving unit disposed within the first moving unit; a first driving unit for moving the first moving part in the optical axis direction; and a second driving unit for moving the second moving unit in a direction perpendicular to the optical axis direction, wherein the second driving unit may include a second magnet disposed on the second moving unit, a second coil disposed on the fixed unit, and a second sensor, wherein the second coil may include an inner surface and an outer surface, and the second sensor may include two sensors disposed by being spaced apart from the inner surface of the second coil, and the shortest distance between the two sensors may be greater than the shortest distance between at least one of the two sensors and the inner surface of the second coil.

### Advantageous Effects

According to the present embodiments, an increased OIS correction angle can be corrected by arranging two Hall sensors in each axis direction in the OIS driving structure.

Furthermore, even if the driving stroke increases, precise OIS correction can be implemented because the two Hall sensors spaced apart from each other can detect the magnet.

### BRIEF DESCRIPTIONS OF DRAWINGS

FIG. 1 is a perspective view of a lens driving device according to an embodiment of the present invention.

FIG. 2 is an exploded perspective view of the lens driving device according to an embodiment of the present invention.

FIG. 3 is a perspective view of the lens driving device according to an embodiment of the present invention with a cover and an AF carrier omitted.

FIGS. 4 and 5 are schematic diagrams showing the arrangement of the OIS magnet, OIS coil, and OIS sensor according to an embodiment of the present invention.

FIG. 6 is a perspective view of a lens driving device according to another embodiment of the present invention with a cover and an AF carrier omitted.

FIGS. 7 and 8 are diagrams illustrating the arrangement of the OIS magnet, OIS coil, and OIS sensor according to another embodiment of the present invention.

FIG. 9 is an exploded perspective view of a camera device according to an embodiment of the present invention.

FIG. 10 is a perspective view of an optical instrument according to an embodiment of the present invention.

FIG. 11 is a perspective view of the optical instrument according to a modified embodiment of the present invention.

### BEST MODE

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Still furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

The term ‘optical axis direction’ used herein refers to the optical axis direction of a lens and/or an image sensor coupled to the lens driving device.

The term ‘vertical direction’ used herein may be parallel to or in the same direction as the optical axis direction. The vertical direction may correspond to the ‘z-axis direction.’ The term ‘horizontal direction’ used herein may be perpendicular to the vertical direction. That is, the horizontal direction may be perpendicular to the optical axis. Therefore, the horizontal direction may include the ‘x-axis direction’ and the ‘y-axis direction.’

The ‘auto focus (AF, auto focus) function’ used hereinafter is defined as the function that automatically adjusts the focus on a subject by moving the lens in the optical axis direction according to the distance to the subject, thereby controlling the distance between the image sensor and the subject to obtain a clear image of the subject on the image sensor. Additionally, “closed-loop auto focus (CLAF) control” is defined as a method of improving the accuracy of focus adjustment by detecting the distance between the image sensor and the lens and providing real-time feedback control to adjust the lens position.

The term ‘hand shake correction (OIS, optical image stabilization) function’ used herein refers to a function that prevents images or videos from shaking due to user hand movement by moving or tilting the lens in a direction perpendicular to the optical axis to counteract the hand movement. Additionally, ‘hand shake correction feedback (CLAF, closed-loop auto focus) control’ is defined as the process of detecting the position of the lens relative to the image sensor and providing real-time feedback (feedback, feedback control) to adjust the lens position in order to improve the accuracy of hand shake correction.

Hereinafter, either the ‘AF moving unit’ or the ‘OIS moving unit’ may be referred to as the ‘first moving unit,’ and the other may be referred to as the ‘second moving unit.’

Hereinafter, either the ‘AF driving unit (400)’ or the ‘OIS driving unit’ may be referred to as the ‘first driving unit,’ and the other may be referred to as the ‘second driving unit.’

Hereinafter, either the ‘AF driving unit (400)’, ‘OIS-x driving unit (500)’, or ‘OIS-y driving unit (600)’ may be referred to as the ‘first driving unit’, the other as the ‘second driving unit’, and the remaining one as the ‘third driving unit’.

Hereinafter, one of ‘AF magnet (410)’, ‘OIS-x magnet (510)’ and ‘OIS-y magnet (610)’ may be referred to as ‘first magnet’, another as ‘second magnet’ and still another as ‘third magnet’.

Hereinafter, one of ‘AF coil (420)’, ‘OIS-x coil (520)’ and ‘OIS-y coil (620)’ may be referred to as the ‘first coil’, another as the ‘second coil’, and the remaining one as the ‘third coil’.

Hereinafter, any one of the ‘AF magnet (410)’, ‘OIS-x magnet (510)’, ‘OIS-y magnet (610)’, ‘AF coil (420)’, ‘OIS-x coil (520)’, and ‘OIS-y coil (620)’ may be referred to as the ‘first driving unit,’ another as the ‘second driving unit,’ another as the ‘third driving unit,’ another as the ‘fourth driving unit,’ another as the ‘fifth driving unit,’ and another as the ‘sixth driving unit.’

In the ensuing text, one of the ‘AF sensor (430)’, ‘OIS-x sensor (530)’, and ‘OIS-y sensor (630)’ may be referred to as the ‘first sensor’, another as the ‘second sensor’, and still another as the ‘third sensor’.

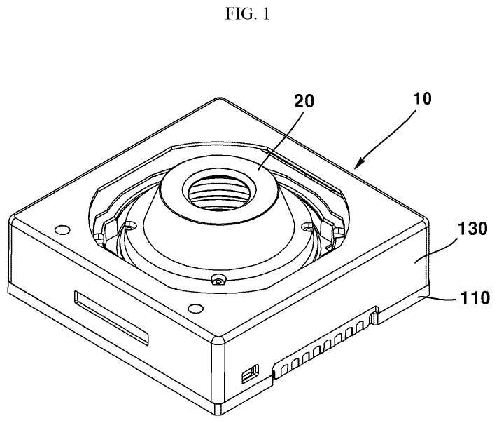

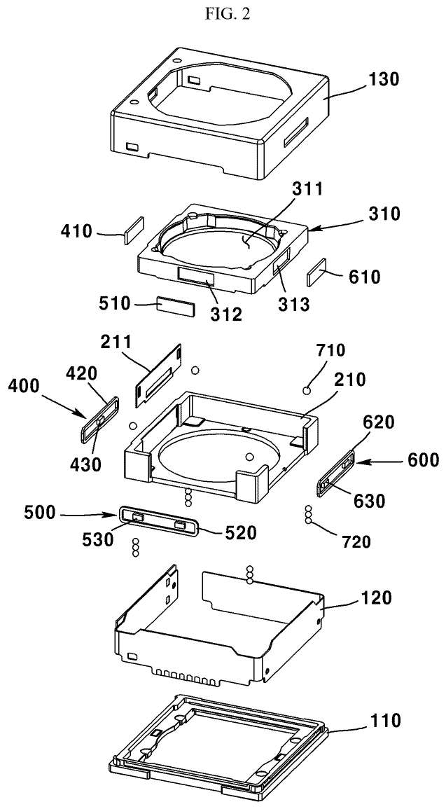

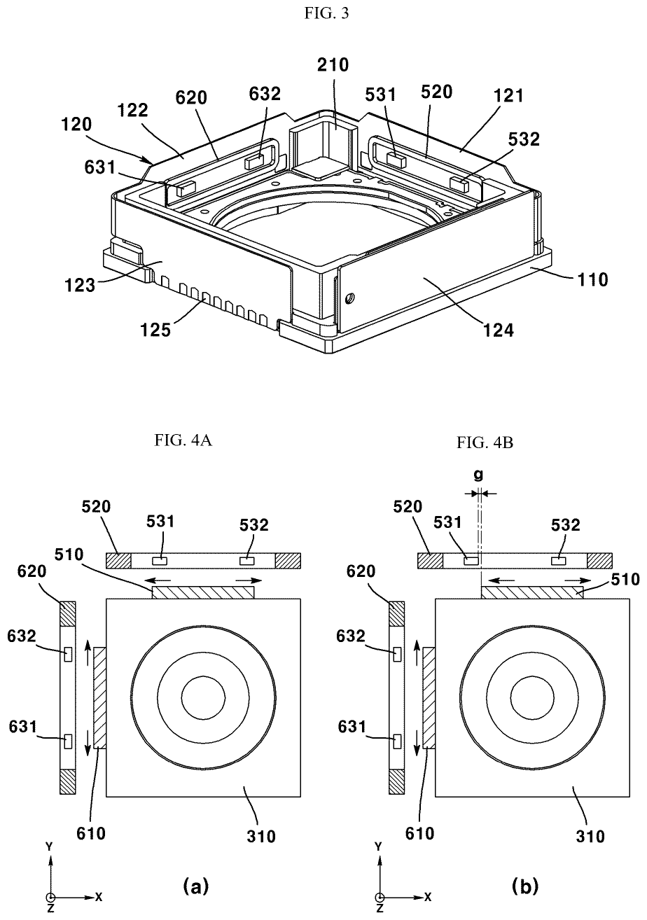

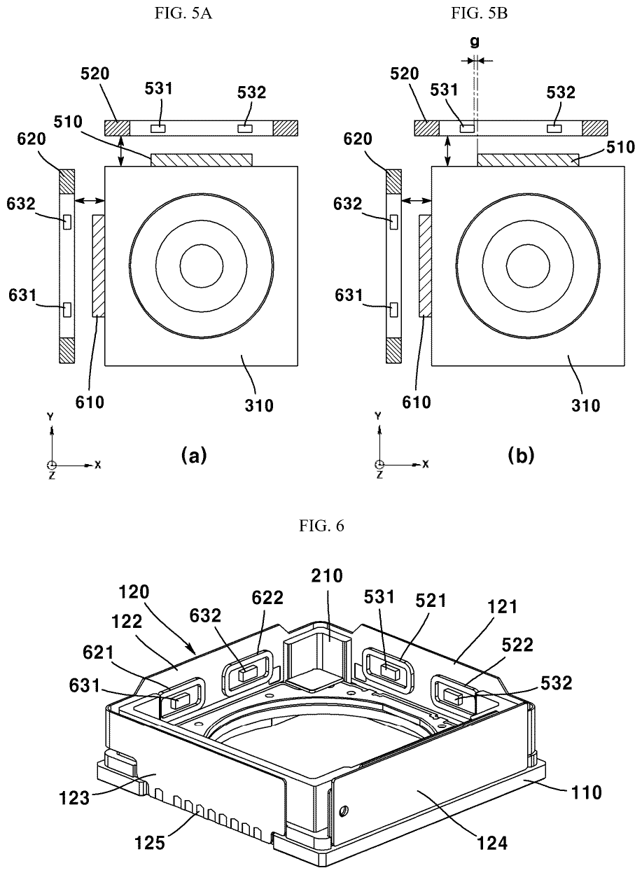

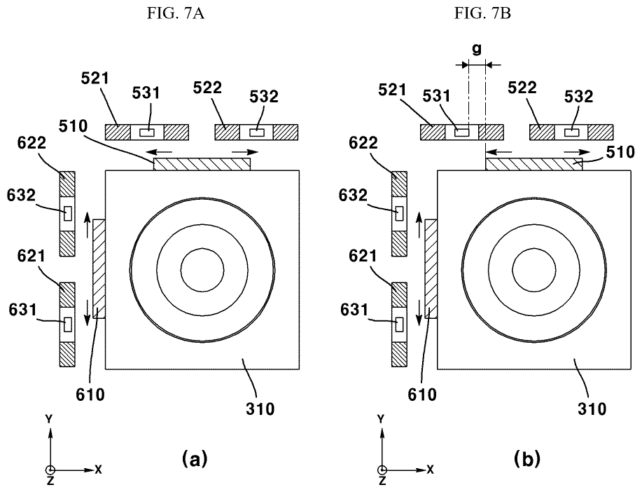

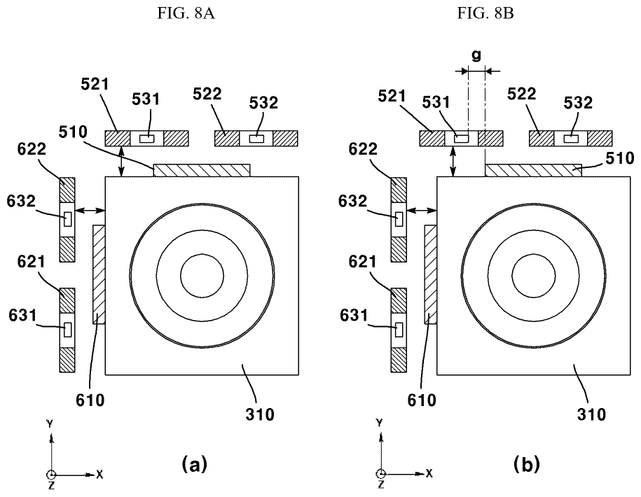

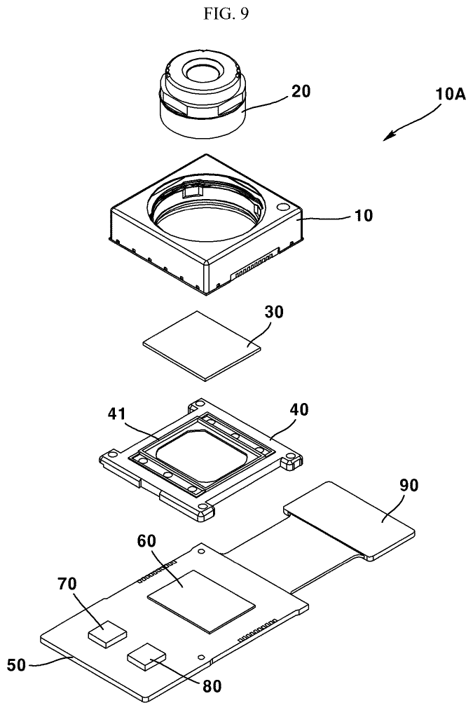

FIG. 1 is a perspective view of a lens driving device according to an embodiment of the present invention, FIG. 2 is an exploded perspective view of the lens driving device according to an embodiment of the present invention, FIG. 3 is a perspective view of the lens driving device according to an embodiment of the present invention with a cover and an AF carrier omitted, FIGS. 4 and 5 are schematic diagrams showing the arrangement of the OIS magnet, OIS coil, and OIS sensor according to an embodiment of the present invention, FIG. 6 is a perspective view of a lens driving device according to another embodiment of the present invention with a cover and an AF carrier omitted, and FIGS. 7 and 8 are diagrams illustrating the arrangement of the OIS magnet, OIS coil, and OIS sensor according to another embodiment of the present invention.

A lens driving device (10) may be a voice coil motor (VCM). The lens driving device (10) may be a lens driving motor. The lens driving device (10) may be a lens driving actuator. The lens driving device (10) may include an AF module. The lens driving device (10) may include an OIS module. The lens driving device (10) may include a fixed unit. The fixed unit may be a portion that remains relatively fixed when a moving unit moves. The moving unit may move relative to the fixed unit. The lens driving device (10) may include a base (110). The fixed unit may include the base (110). The base (110) may be disposed below an AF carrier (210). The base (110) may be disposed below an OIS carrier (310). The base (110) may be coupled to a cover (130). The AF carrier (210) and the OIS carrier (310) may be disposed on the base (110). The AF carrier (210) and the OIS carrier (310) may be disposed on a lower plate portion of the base (110). The AF carrier (210) and the OIS carrier (310) may be disposed within the base (110). The base (110) may include a lower plate portion. The lower plate portion of the base (110) may support the lower surface of the AF moving unit. The lower plate portion of the base (110) may support the lower surface of the AF carrier (210).

The base (110) may include a staircase. The staircase may be formed at a lower end portion of the outer surface of the base (110). The staircase may protrude from the outer surface of the base (110).

The staircase of the base (110) may be disposed with a side plate of the cover (130). The staircase of the base (110) may be disposed with a substrate (120). The lens driving device (10) may include the substrate (120). The substrate (120) may include a flexible printed circuit board (FPCB). The substrate (120) may be electrically connected to the coils (420, 520, 620). The substrate (120) may be electrically connected to the sensors (430, 530, 630). The substrate (120) may be disposed on the base (110). The substrate (120) may include a flexible substrate. The substrate (120) may include a flexible printed circuit board (FPCB). The substrate (120) may include an elastic portion. The substrate (120) may include four substrates (121, 122, 123, 124) disposed on the four sides of the base (110). The four substrates (121, 122, 123, 124) may be formed to wrap around the sides of the base (110). The four substrates (121, 122, 123, 124) may include a first substrate (121) and a third substrate (123) disposed opposite each other, and a second substrate (122) and a fourth substrate (124) disposed opposite each other. At least one of the four substrates (121, 122, 123, 124) may include a terminal portion. The four substrates (121, 122, 123, 124) may include two terminal portions. The two terminal portions may be disposed on opposite sides with respect to the optical axis. The terminal portion may include a terminal.

The substrate (120) may include terminals. The terminals may be disposed at the lower end portion of the base (110). The terminals may be coupled to the printed circuit board (50). The terminals may be coupled to the terminals of the printed circuit board (50) via solder. The terminals may be coupled to the terminals of the printed circuit board (50) via a conductive member. The terminals may be connected to the terminals of the printed circuit board (50). The terminals may be electrically connected to the terminals of the printed circuit board (50).

The lens driving device (10) may include a cover (130). The fixing unit may include the cover (130). The cover (130) may be disposed at the base (110). The cover (130) may be disposed on the base (110). The cover (130) may be coupled to the base (110). The cover (130) may be fixed to the base (110). The cover (130) may accommodate an AF carrier (210) internally. The cover (130) may accommodate an OIS carrier (310) internally. The cover (130) may be a shield member. The cover (130) may be a shield can.

The cover (130) may include an upper plate. The upper plate may be disposed on the moving unit. The upward movement of the moving unit may be restricted by the moving unit coming into contact with the upper plate. The upper plate may include a hole through which light can pass.

The cover (130) may include a side plate. The side plate may extend from the upper plate. The side plate may be disposed on the base (110). The side plate may be disposed on a staircase portion formed on the lower end portion of the outer surface of the base (110). The side plate may include a plurality of side plates. The side plate may include four side plates. The side plate may include a first side plate and a third side plate disposed on opposite sides, and a second side plate and a fourth side plate disposed on opposite sides.

The lens driving device (10) may include a moving unit. The moving unit may be disposed on the fixed unit. The moving unit may be disposed within the fixed unit. The moving unit may be disposed on the fixed unit. The moving unit may be movably disposed on the fixed unit. The moving unit may be moved relative to the fixed unit by a driving unit. The moving unit may be moved during AF driving. The moving unit may be moved during OIS driving. A lens may be coupled to the moving unit.

The lens driving device (10) may include an AF moving unit. The AF moving unit may be disposed on the fixed unit. The AF moving unit may be disposed within the fixed unit. The AF moving unit may be disposed on the fixed unit. The AF moving unit may be disposed between the fixed unit and the OIS moving unit. The AF moving unit may be movably disposed on the fixed unit. The AF moving unit may be moved in the optical axis direction relative to the fixed unit by an AF driving unit (400). The AF moving unit may move during AF operation.

In the modified example, the AF moving unit and the AF driving unit (400) may be omitted. That is, the OIS moving unit may be disposed on the fixed unit. Alternatively, the OIS moving unit may be disposed on the fixed unit, and the AF moving unit may be disposed within the OIS moving unit.

The lens driving device (10) may include an AF carrier (210). The AF moving unit may include the AF carrier (210). The AF carrier (210) may be an “AF holder”. The AF carrier (210) may be a “housing”. The AF carrier (210) may be disposed within the base (110). The AF carrier (210) may be disposed on the base (110). The AF carrier (210) may be disposed within the cover (130). The AF carrier (210) may be disposed between the base (110) and the OIS carrier (310). The AF carrier (210) may be disposed so as to be movable in the optical axis direction.

The AF carrier (210) may include a lower plate. The lower plate may be disposed on the base (110). The lower plate may be disposed between the OIS carrier (310) and the lower plate of the base (110).

The AF carrier (210) may include a side wall. The side wall may extend upward from the lower plate. The substrate (120) may be disposed on the side wall. An AF coil (420) may be disposed on the side wall. An OIS-x coil (520) may be disposed on the side wall. An OIS-y coil (620) may be disposed on the side wall. The side wall may include a groove that avoids the coils. The side wall may include multiple side walls. The side wall may include four side walls. The side walls may include a first side wall and a second side wall disposed on opposite sides, and a third side wall and a fourth side wall disposed on opposite sides.

The AF carrier (210) may include a hole. The hole may be formed in the side wall of the AF carrier (210). The hole may be open inwardly. A preload member (211) may be inserted into the hole. The hole may be formed as a groove. The hole may be replaced by a groove

The lens driving device (10) may include an OIS moving unit. The OIS moving unit may be disposed in the fixed unit. The OIS moving unit may be disposed within the fixed unit. The OIS moving unit may be disposed on the fixed unit. The OIS moving unit may be disposed within the AF moving unit. The OIS moving unit may be disposed movably. The OIS moving unit can be moved in a direction perpendicular to the optical axis relative to the fixed unit and the AF moving unit by the OIS driving unit. The OIS moving unit can be moved in the x-axis direction by an OIS-x driving unit (500). The OIS moving unit can be moved in the y-axis direction by an OIS-y driving unit (600). The OIS moving unit can be moved during OIS operation.

The lens driving device (10) may include an OIS carrier (310). The OIS moving unit may include an OIS carrier (310). The OIS carrier (310) may be an “OIS holder”. The OIS carrier (310) may be a “bobbin”. The OIS carrier (310) may be disposed within the AF carrier (210). The OIS carrier (310) may be disposed within the base (110). The OIS carrier (310) may be disposed on the base (110). The OIS carrier (310) may be disposed within the cover (130). The OIS carrier (310) may be disposed so as to be movable in a direction perpendicular to the optical axis.

The OIS carrier (310) may include an outer surface. The OIS carrier (310) may include multiple sides. The OIS carrier (310) may include a first side and a third side disposed opposite each other, and a second side and a fourth side disposed opposite each other. The multiple sides of the OIS carrier (310) may include at least one groove.

The groove of the OIS carrier (310) may have the OIS-x magnet (510) and the OIS-y magnet (610) disposed therein. The AF coil (420) may be disposed between the first side of the OIS carrier (310) and the AF magnet (410). The OIS-x magnet (510) may be disposed on the second side of the OIS carrier (310). The OIS-y magnet (610) may be disposed on the third side of the OIS carrier (310). The lens driving device (10) may include a driving unit. The driving unit can move the moving unit relative to the fixed unit. The driving unit may include an AF driving unit (400). The driving unit may include an OIS driving unit. The driving unit may include an OIS-x driving unit (500). The driving unit may include an OIS-y driving unit (600). The driving unit may include a coil and a magnet. The lens driving device (10) may include an AF driving unit (400). The AF driving unit (400) may move the AF moving unit in the optical axis direction. The AF driving unit (400) may move the AF carrier (210) in the optical axis direction. The AF driving unit (400) can move the AF carrier (210) in the optical axis direction through electromagnetic force. The AF driving unit (400) may include a coil and a magnet.

In the present embodiment, the AF carrier (210) and the OIS carrier (310) can move in the optical axis direction due to the interaction between the AF coil (420) and the AF magnet (410). The AF coil (420), the AF carrier (210), and the OIS carrier (310) can move integrally in the optical axis direction.

The lens driving device (10) may include an AF magnet (410). The AF driving unit (400) may include an AF magnet (410). The AF magnet (410) may be an “AF magnet”. The AF magnet (410) may be a permanent magnet. The AF magnet (410) may be disposed on the fixed unit. The AF magnet (410) may be disposed on the base (110). The AF magnet (410) may be disposed on the cover (130). The AF magnet (410) may be disposed on the side plate of the cover (130). AF magnet (410) may be disposed on the outer surface of the base (110). AF magnet (410) may be disposed on the inner surface of the base (110). AF magnet (410) may be fixed to the base (110). AF magnet (410) may be coupled to the base (110). The AF magnet (410) may be coupled to the base (110) with an adhesive. The AF magnet (410) may be disposed within the cover (130). The AF magnet (410) may interact with the AF coil (420). The AF magnet (410) can interact electromagnetically with the AF coil (420). The AF magnet (410) may be disposed in a corresponding location relative to the AF coil (420). The AF magnet (410) may face the AF coil (420). The AF magnet (410) may be opposed to the AF coil (420).

The AF magnet (410) may overlap with the AF coil (420) in a direction perpendicular to the optical axis.

The lens driving device (10) may include an AF coil (420). The AF driving unit (400) may include the AF coil (420). The AF coil (420) may interact with the AF magnet (410). The AF coil (420) may face the AF magnet (410). The AF coil (420) may face the AF magnet (410). The AF coil (420) may be disposed at a corresponding location relative to the AF magnet (410). The AF coil (420) may overlap with the AF magnet (410) in a direction perpendicular to the optical axis. The AF coil (420) may be disposed on the AF carrier (210). The AF coil (420) may be disposed on the AF moving unit.

In the present embodiment, the AF coil (420) may move in the optical axis direction. The AF coil (420) may move in the optical axis direction through interaction with the AF magnet (410). The AF coil (420) can move together with the AF moving unit. The AF coil (420) can move in the optical axis direction together with the AF moving unit. During the AF driving process, the AF coil (420) can move in the optical axis direction together with the AF moving unit. The AF coil (420) may be disposed in the AF moving unit. The AF coil (420) may be fixed to the AF moving unit. The AF coil (420) may be coupled to the AF moving unit.

The lens driving device (10) may include an AF sensor (430). The AF driving unit (400) may include an AF sensor (430). The AF sensor (430) may be a Hall sensor. The AF sensor (430) may be disposed on an inner substrate (720). The AF sensor (430) may detect the AF magnet (410). The AF sensor (430) may detect the movement of the AF magnet (410). The amount of movement or position of the AF magnet (410) detected by the AF sensor (430) may be used as feedback for the autofocus driving. The AF sensor (430) may be a driver IC. The driver IC may include a sensing unit. The sensing unit may include a Hall element (Hall IC). The driver IC may be electrically connected to the AF coil (420). The driver IC may supply a current to the AF coil (420). The AF sensor (430) may be disposed within the AF coil (420). The AF sensor (430) may overlap with the AF magnet (410) in a direction perpendicular to the optical axis. As a modified alternative example, the AF sensor (430) may be disposed on the outer side of the AF coil (420). The AF sensor (430) may overlap with the AF coil (420) in the optical axis direction. The AF sensor (430) may overlap with the AF coil (420) in a direction perpendicular to the optical axis.

The lens driving device (10) may include an AF yoke. The AF yoke may be disposed at a location corresponding to the AF magnet (410). An attractive force may act between the AF yoke and the AF magnet (410). The AF yoke may be disposed on the preload member (211). The AF yoke may be disposed on the inner side of the AF coil (420).

The lens driving device (10) may include an OIS driving unit. The OIS driving unit may move the OIS moving unit in a direction perpendicular to the optical axis. The OIS driving unit may move the OIS carrier (310) in a direction perpendicular to the optical axis. The OIS driving unit may move the OIS carrier (310) in a direction perpendicular to the optical axis through electromagnetic force.

The lens driving device (10) may include an OIS-x driving unit (500). The OIS driving unit may include an OIS-x driving unit (500). The OIS-x driving unit (500) can move the OIS carrier (310) in the x-axis direction perpendicular to the optical axis. The OIS-x driving unit (500) can move the OIS carrier (310) in the x-axis direction perpendicular to the optical axis using electromagnetic force. The OIS-x driving unit (500) may include a coil and a magnet.

In the present embodiment, the OIS-x magnet (510) and the OIS-x coil (520) can move the OIS moving unit in a first direction perpendicular to the optical axis. At this time, the first direction may be the x-axis direction. Due to the interaction between the OIS-x coil (520) and the OIS-x magnet (510), the OIS carrier (310) can move in the x-axis direction perpendicular to the optical axis. The OIS-x magnet (510) and the OIS carrier (310) may move together in the x-axis direction.

The lens driving device (10) may include an OIS-x magnet (510). The OIS driving unit may include the OIS-x magnet (510). The OIS-x magnet (510) may be an “OIS-x magnet”. The OIS-x magnet (510) may be a permanent magnet. The OIS-x magnet (510) may be disposed in the OIS moving unit. The OIS-x magnet (510) may be spaced apart from the AF magnet (410). The OIS-x magnet (510) may be disposed on the OIS carrier (310). The OIS-x magnet (510) may be disposed on the outer surface of the OIS carrier (310). The OIS-x magnet (510) may be fixed to the OIS carrier (310). The OIS-x magnet (510) may be coupled to the OIS carrier (310). The OIS-x magnet (510) may be coupled to the OIS carrier (310) using an adhesive. The OIS-x magnet (510) may be disposed within the cover (130). The OIS-x magnet (510) may interact with the OIS-x coil (520). The OIS-x magnet (510) may electromagnetically interact with the OIS-x coil (520). The OIS-x magnet (510) may be disposed at a corresponding location relative to the OIS-x coil (520). The OIS-x magnet (510) may face the OIS-x coil (520). The OIS-x magnet (510) may be oriented oppositely to the OIS-x coil (520). The OIS-x magnet (510) may overlap with the OIS-x coil (520) in a direction perpendicular to the optical axis. The OIS-x magnet (510) may overlap with the OIS-x coil (520) in the x-axis direction. The OIS-x magnet (510) can move in the x-axis direction perpendicular to the optical axis.

The lens driving device (10) may include an OIS-x coil (520). The OIS driving unit may include the OIS-x coil (520). The OIS-x coil (520) may interact with the OIS-x magnet (510). The OIS-x coil (520) can move the OIS-x magnet (510) in the x-axis direction perpendicular to the optical axis. The OIS-x coil (520) can move the OIS-x magnet (510) in the x-axis direction through interaction with the OIS-x magnet (510). The OIS-x coil (520) may be disposed opposite the OIS-x magnet (510). The OIS-x coil (520) may face the OIS-x magnet (510). The OIS-x coil (520) may be disposed at a location corresponding to the OIS-x magnet (510). The OIS-x coil (520) may overlap with the OIS-x magnet (510) in a direction perpendicular to the optical axis. The OIS-x coil (520) may be disposed on the AF carrier (210).

In the present embodiment, the OIS-x coil (520) can move together with the AF moving unit. The OIS-x coil (520) can move in the optical axis direction together with the AF moving unit. During the AF driving process, the OIS-x coil (520) may move in the optical axis direction together with the AF moving unit. The OIS-x coil (520) may be disposed on the AF moving unit. The OIS-x coil (520) may be fixed to the AF moving unit. The OIS-x coil (520) may be coupled to the AF moving unit.

The lens driving device (10) may include an OIS-x sensor (530). The OIS driving unit may include an OIS-x sensor (530). The OIS-x sensor (530) may include a Hall sensor. The OIS-x sensor (530) may detect the OIS-x magnet (510). The OIS-x sensor (530) may detect the magnetic force of the OIS-x magnet (510). The OIS-x sensor (530) may be disposed on the upper side of the OIS-x magnet (510). The OIS-x sensor (530) can overlap with the OIS-x magnet (510) in the optical axis direction. As a modified example, the OIS-x sensor (530) may be disposed within the OIS-x coil (520). The OIS-x sensor (530) may overlap with the OIS-x coil (520) in the optical axis direction. The OIS-x sensor (530) may overlap with the OIS-x coil (520) in a direction perpendicular to the optical axis. The OIS-x sensor (530) may be opposed to the OIS-x magnet (510). The OIS-x sensor (530) may be disposed at a corresponding location relative to the OIS-x magnet (510). The OIS-x sensor (530) may detect the movement of the OIS-x magnet (510). The amount of movement or position of the OIS-x magnet (510) detected by the OIS-x sensor (530) may be used as feedback for hand shake correction driving to the x-axis direction.

The lens driving device (10) may include an OIS-x yoke. The OIS-x yoke may be disposed in the OIS-x magnet (510). The OIS-x yoke may be disposed between the OIS-x magnet (510) and the OIS carrier (310). The OIS-x yoke can prevent magnetic flux leakage from the OIS-x magnet (510), thereby enhancing the interaction force with the OIS-x coil (520).

When viewed from above, the AF magnet (410), AF coil (420), OIS-y magnet (610), and OIS-y coil (620) may be disposed in sequence along a virtual straight line. When viewed from an upper surface, the AF magnet (410), AF coil (420), OIS-y magnet (610), and OIS-y coil (620) may be disposed in order along a virtual straight line. When viewed from above, the AF magnet (410), AF coil (420), OIS-y magnet (610), and OIS-y coil (620) may be disposed in order. When viewed from above, the AF magnet (410), AF coil (420), OIS-y magnet (610), and OIS-y coil (620) may be disposed in order along the y-axis. When viewed from above, the AF magnet (410), AF coil (420), OIS-y magnet (610), and OIS-y coil (620) may be overlapped in the y-axis direction.

The lens driving device (10) may include a guide member (not shown). The guide member may include a ball. The guide member may include a pin. The guide member may include a cylindrical member. The guide member may guide the movement of the moving unit relative to the fixed unit in a specific direction.

The lens driving device (10) may include an AF guide ball (720). The AF guide ball (720) may include a plurality of ball bearings disposed along the optical axis direction. The AF guide ball (720) may guide the movement of the AF moving unit relative to the fixed unit in the optical axis direction. The AF guide ball (720) can guide the movement of the AF carrier (210) relative to the base (110) in the optical axis direction. The AF guide ball (720) may be disposed between the fixed unit and the AF moving unit. The AF guide ball (720) may be disposed between the base (110) and the AF carrier (210). The AF guide ball may be disposed between the base (110) and the AF carrier (210) in the x-direction. Alternatively, the AF guide ball may be disposed between the base (110) and the AF carrier (210) in the y-direction. The base (110) may include a side wall extending upward from the lower plate, unlike those shown in FIG. 1. The side wall of the base (110) may have a recessed groove formed inwardly to accommodate the AF guide ball (720). The AF guide ball may be disposed in the groove of the base (110). The AF guide ball may be disposed in the groove of the AF carrier (210). The AF guide ball may be spherical in shape. The AF guide ball may be formed of metal. The surface of the AF guide ball may be coated with grease.

The lens driving device (10) may include an OIS guide member. The OIS guide member may be a guide member. The OIS guide member is a guide plate. The OIS guide member may be a guide plate. The OIS guide member may be a guide structure.

The OIS guide member may guide the movement of the AF carrier (210) relative to the OIS carrier (310) in a direction perpendicular to the optical axis. The OIS guide member may be disposed between the AF moving unit and the OIS moving unit. The OIS guide member may be disposed between the AF carrier (210) and the OIS carrier (310). The OIS guide member may be disposed between the AF carrier (210) and the OIS carrier (310) in the optical axis direction. The OIS guide member may be referred to as a moving member. An OIS ball bearing unit (710) may be positioned between the AF carrier (210) and the OIS guide member. An OIS ball bearing unit (710) may be disposed between the OIS carrier (310) and the OIS guide member. The carrier (310) may have an inwardly recessed groove formed at the lower plate corner portion to accommodate the OIS ball bearing unit (710). The AF carrier (210) may have a recessed groove formed inwardly on the lower plate to accommodate the OIS ball bearing unit (710).

The lens driving device (10) may include an elastic member (not shown). The elastic member may be formed to support the OIS driving. The elastic member may support the movement of the OIS moving unit. The elastic member may be formed to press the OIS guide member. The elastic member may be formed to guide both OIS-x-axis driving and OIS-y-axis driving using only the OIS guide member. The elastic member may include a plate spring. The elastic member may include a wire. The elastic member may have elasticity. The elastic member may be formed of metal.

The elastic member can press the OIS guide member in the direction of the AF moving unit. The elastic member can press the OIS moving unit in the direction of the AF moving unit. In this case, the elastic member may include an upper elastic member, a lower elastic member, and a wire.

Hereinafter, the OIS-x coil and OIS-y coil that constitute the hand shake correction (Optical Image Stabilization (OIS)} driving unit of the lens driving device according to the present embodiment will be described with reference to FIGS. 3 to 5. Hereinafter, the “x-axis direction” may be referred to as the “first direction,” and the “y-axis direction” may be referred to as the “second direction.” The x-axis direction and the y-axis direction may be perpendicular to the optical axis, and the x-axis direction and the y-axis direction may be perpendicular to each other.

The OIS-x coil (520) and OIS-x sensor (530) according to the present embodiment may be disposed on a single substrate and the OIS-y coil (620) and OIS-y sensor (630) may be disposed on a different substrate. The “OIS-x coil (520) and OIS-x sensor (530)” and “OIS-y coil (620) and OIS-y sensor (630)” may be disposed on different substrates adjacent to each other. For example, a first substrate (121) and a second substrate (122) may be disposed adjacent to each other, and the “OIS-x coil (520) and OIS-x sensor (530)” may be disposed on the first substrate (121), while the ‘OIS-y coil (620) and OIS-y sensor (630)’ may be disposed on the second substrate (122). The first substrate (121) and the second substrate (122) may be disposed vertically relative to each other. The “OIS-x coil (520) and OIS-x sensor (530)” may be disposed to face the OIS-x magnet (510). The “OIS-y coil (620) and OIS-y sensor (630)” may be disposed to face the OIS-y magnet (610).

The AF sensor (430) and the OIS sensors (530, 630) may be disposed on opposite sides. The AF sensor (430) and the OIS-x sensor (530) may be disposed on opposite sides. The AF sensor (430) and the OIS-y sensor (630) may be disposed on opposite sides. The AF sensor (430) may be disposed on a third substrate opposite the first substrate (121). The AF sensor (430) may be disposed on a fourth substrate opposite the second substrate (122). The number of AF sensors (430) may be fewer than the number of OIS sensors (530, 630). The AF sensor (430) may be disposed to face the AF magnet (410). The AF sensor (430) may be disposed to face the AF carrier (210). The AF sensor (430) may be disposed within the AF coil (420).

The OIS-x sensor (530) can sense the position and movement of the OIS-x magnet (510). The OIS-x sensor (530) can sense the movement of the OIS carrier (310) in the x-axis direction. The OIS-y sensor (630) can sense the position and movement of the OIS-y magnet (610). The OIS-y sensor (630) can sense the movement of the OIS carrier (310) in the y-axis direction.

A substrate may be disposed between the AF carrier (210) and the cover (130). The substrate may be disposed between the OIS carrier (310) and the cover (130). The substrate may be disposed on the side of the fixed unit. The AF carrier (210) may include a first side wall and a second side wall adjacent to each other. The first substrate (121) may be disposed facing the first side wall of the AF carrier (210). The second substrate (122) may be disposed facing the second side wall of the AF carrier (210). The OIS carrier (310) may include first and second side walls adjacent to each other. The first substrate (121) may be disposed to face the first side wall of the OIS carrier (310). The second substrate (122) may be disposed to face the second side wall of the OIS carrier (310).

The OIS-x coil (520) and the OIS-y coil (620) may be formed in a ring shape. The OIS-x coil (520) and the OIS-y coil (620) may be formed in a ring shape, with lengths corresponding to the sides of the OIS carrier (310). The OIS-x coil (520) may be disposed to surround the OIS-x sensor (530). The OIS-y coil (620) may be disposed to surround the OIS-y sensor (630). The OIS-x coil (520) may be formed longer than the OIS-x magnet (510). The OIS-y coil (620) may be formed longer than the OIS-y magnet (610).

The OIS-x sensor (530) may be disposed inside the ring of the OIS-x coil (520). The OIS-x sensor (530) may be disposed in a hole of the OIS-x coil (520). The OIS-x sensor (530) may include two sensors disposed inside the ring of the OIS-x coil (520). The OIS-x sensor (530) may include a first OIS-x sensor (531) and a second OIS-x sensor (532) disposed in a spaced-apart manner. The first OIS-x sensor (531) and the second OIS-x sensor (532) may be disposed symmetrically within the ring of the OIS-x coil (520). The center of the OIS-x coil (520) and the centers of the first OIS-x sensor (531) and the second OIS-x sensor (532) may be the same.

The length of the OIS-x magnet (510) in the x-axis direction may be shorter than the length of the OIS-x coil (520) in the x-axis direction. The length of the OIS-x magnet (510) in the x-axis direction may be longer than the distance between the first OIS-x sensor (531) and the second OIS-x sensor (532). A first end (or step or stage) of the first OIS-x sensor (531) may face the OIS-x coil (520), and a second end (or step or stage) opposite the first end may face the second OIS-x sensor (532). The first end of the second OIS-x sensor (532) may face the first OIS-x sensor (531), and the second end on the opposite side of the first end faces the OIS-x coil (520). The length of the OIS-x magnet (510) in the x-axis direction may be longer than the distance between the first end of the first OIS-x sensor (531) and the second end of the second OIS-x sensor (532). The length of the OIS-x magnet (510) in the x-axis direction may be longer than the distance between the second end of the first OIS-x sensor (531) and the first end of the second OIS-x sensor (532).

The distance between the first OIS-x sensor (531) and the second OIS-x sensor (532) in the x-axis direction may be greater than the distance between the first end of the first OIS-x sensor (531) and an inner wall of the OIS-x coil (520). The distance between the first OIS-x sensor (531) and the second OIS-x sensor (532) in the x-axis direction may be greater than the distance between the second end of the second OIS-x sensor (532) and the inner wall of the OIS-x coil (520). The shortest distance between the first OIS-x sensor (531) and the second OIS-x sensor (532) in the x-axis direction may be greater than the shortest distance between at least one of the first OIS-x sensor (531) and the second OIS-x sensor (532) and the inner surface of the OIS-x coil (520).

The OIS-y sensor (630) may be disposed within the ring of the OIS-y coil (620). The OIS-y sensor (630) may be disposed in the hole of the OIS-y coil (620). The OIS-y sensor (630) may include two sensors disposed within the ring of the OIS-y coil (620). The OIS-y sensor (630) may include a first OIS-y sensor (631) and a second OIS-y sensor (632) disposed in a spaced-apart manner. The first OIS-y sensor (631) and the second OIS-y sensor (632) may be disposed symmetrically within the ring of the OIS-y coil (620). The center of the OIS-y coil (620) and the centers of the first OIS-y sensor (631) and the second OIS-y sensor (632) may be the same.

The length of the OIS-y magnet (610) in the y-axis direction may be shorter than the length of the OIS-y coil (620) in the y-axis direction. The length of the OIS-y magnet (610) in the y-axis direction may be longer than the distance between the first OIS-y sensor (631) and the second OIS-y sensor (632). The first end of the first OIS-y sensor (631) may face the OIS-y coil (620), and the second end on the opposite side of the first end may face the second OIS-y sensor (632). The first end of the second OIS-y sensor (632) may face the first OIS-y sensor (631), the second end on the opposite side of the first end may face the OIS-y coil (620). The length of the y-axis direction of the OIS-y magnet (610) may be longer than the distance between the first end of the first OIS-y sensor (631) and the second end of the second OIS-y sensor (632). The length of the y-axis direction of the OIS-y magnet (610) may be longer than the distance between the second end of the first OIS-y sensor (631) and the first end of the second OIS-y sensor (632).

The distance between the first OIS-y sensor (631) and the second OIS-y sensor (632) in the y-axis direction may be greater than the distance between the first end of the first OIS-y sensor (631) and the inner wall of the OIS-y coil (620). In the y-axis direction, the distance between the first OIS-y sensor (631) and the second OIS-y sensor (632) may be greater than the distance between the second end of the second OIS-y sensor (632) and the inner wall of the OIS-y coil (620). The shortest distance between the first OIS-y sensor (631) and the second OIS-y sensor (632) in the y-axis direction may be greater than the shortest distance between at least one of the first OIS-y sensor (631) and the second OIS-y sensor (632) and the inner surface of the OIS-y coil (620).

The first OIS-x sensor (531) and the second OIS-x sensor (532) may overlap with the OIS-x magnet (510) disposed on the OIS carrier (310) in the y-axis direction. At an initial position where the OIS carrier (310) is stationary, the first OIS-x sensor (531) and the second OIS-x sensor (532) may overlap with the OIS-x magnet (510) in the y-axis direction. The initial position may refer to the position of the OIS carrier (310) when no driving current is applied to the coils. The initial position may refer to the position of the OIS carrier (310) when it has not moved. When the OIS carrier (310) has moved, the OIS-x magnet (510) may overlap with at least one of the first OIS-x sensor (531) and the second OIS-x sensor (532) in the y-axis direction.

Referring to FIG. 4, the OIS carrier (310) can be driven in the x-axis direction due to the electromagnetic interaction between the OIS-x magnet (510) and the OIS-x coil (520). Due to the electromagnetic interaction between the OIS-x magnet (510) and the OIS-x coil (520), the OIS carrier (310) can move closer to or farther away from the OIS-y coil (620) in the x-axis direction. At this time, the gap between the OIS carrier (310) and the OIS-x coil (520) in the y-axis direction can be maintained at the same distance.

When the OIS carrier (310) moves to its maximum position in the x-axis direction, either the first OIS-x sensor (531) or the second OIS-x sensor (532) may overlap with the OIS-x magnet (510) in the y-axis direction, while the other may not overlap with the OIS-x magnet (510) in the y-axis direction. When the OIS carrier (310) is at its maximum position in the-x-axis direction, the first OIS-x sensor (531) may overlap with the OIS-x magnet (510) in the y-axis direction, and the second OIS-x sensor (532) may not overlap with the OIS-x magnet (510) in the y-axis direction. When the OIS carrier (310) is at its maximum position in the +x-axis direction, the first OIS-x sensor (531) may not overlap with the OIS-x magnet (510) in the y-axis direction, and the second OIS-x sensor (532) may overlap with the OIS-x magnet (510) in the y-axis direction.

At the position where the OIS carrier (310) has moved maximally in the x-axis direction, a virtual line extending the side of the sensor that does not overlap with the OIS-x magnet (510) in the y-axis direction, among the first OIS-x sensor (531) and the second OIS-x sensor (532), may be disposed spaced apart from a virtual line extending the side of the OIS-x magnet (510) (g).

Referring to FIG. 5, the OIS carrier (310) can be driven in the y-axis direction due to the electromagnetic interaction between the OIS-x magnet (510) and the OIS-x coil (520). Due to the electromagnetic interaction between the OIS-x magnet (510) and the OIS-x coil (520), the OIS carrier (310) can move closer to or farther away from the OIS-x coil (520) in the y-axis direction. At this time, the gap between the OIS carrier (310) and the OIS-x coil (520) in the x-axis direction may be maintained at the same distance.

When the OIS carrier (310) moves to its maximum position in the y-axis direction, either the first OIS-y sensor (631) or the second OIS-y sensor (632) may overlap with the OIS-y magnet (610) in the x-axis direction, while the other may not overlap with the OIS-y magnet (610) in the x-axis direction. When the OIS carrier (310) is at its maximum position in the y-axis direction, the first OIS-y sensor (631) may overlap with the OIS-y magnet (610) in the x-axis direction, and the second OIS-y sensor (632) may not overlap with the OIS-y magnet (610) in the x-axis direction. When the OIS carrier (310) is at its maximum position in the −x-axis direction, the second OIS-y sensor (632) may not overlap with the OIS-y magnet (610) in the x-axis direction, and the first OIS-y sensor (631) may overlap with the OIS-y magnet (610) in the x-axis direction.

At the position where the OIS carrier (310) has moved maximally in the y-axis direction, the first OIS-y sensor (631) and the second OIS-y sensor (632) may be disposed such that a virtual line extending the side of the sensor that does not overlap with the OIS-y magnet (610) in the x-axis direction is spaced apart from a virtual line extending the side of the OIS-y magnet (610).

The first OIS-y sensor (631) and the second OIS-y sensor (632) may overlap with the OIS-y magnet (610) disposed on the OIS carrier (310) in the x-axis direction. At an initial position where the OIS carrier (310) is stationary, the first OIS-y sensor (631) and the second OIS-y sensor (632) may overlap with the OIS-y magnet (610) in the x-axis direction. The initial position may refer to the position of the OIS carrier (310) when no driving current is applied to the coil. The initial position may refer to the position of the OIS carrier (310) when it has not moved. When the OIS carrier (310) has moved, the OIS-y magnet (610) may overlap with at least one of the first OIS-y sensor (631) and the second OIS-y sensor (632) in the x-axis direction.

Referring to FIG. 4, the OIS carrier (310) may be driven in the y-axis direction due to the electromagnetic interaction between the OIS-y magnet (610) and the OIS-y coil (620). Due to the electromagnetic interaction between the OIS-y magnet (610) and the OIS-y coil (620), the OIS carrier (310) may move farther apart from or closer to the OIS-x coil (520) in the y-axis direction. At this time, the gap between the OIS carrier (310) and the OIS-y coil (620) in the x-axis direction may be maintained at the same distance.

At a position where the OIS carrier (310) has moved maximally in the y-axis direction, either the first OIS-y sensor (631) or the second OIS-y sensor (632) may overlap with the OIS-y magnet (610) in the x-axis direction, while the other may not overlap with the OIS-y magnet (610) in the x-axis direction. When the OIS carrier (310) is at its maximum position in the −y-axis direction, the first OIS-y sensor (631) may overlap with the OIS-y magnet (610) in the x-axis direction, and the second OIS-y sensor (632) may not overlap with the OIS-y magnet (610) in the x-axis direction. When the OIS carrier (310) is at its maximum position in the +y-axis direction, the first OIS-y sensor (631) may not overlap with the OIS-y magnet (610) in the x-axis direction, and the second OIS-y sensor (632) may overlap with the OIS-y magnet (610) in the x-axis direction.

At the position where the OIS carrier (310) has moved maximally in the y-axis direction, a virtual line extending the side of the sensor that does not overlap with the OIS-y magnet (610) in the x-axis direction, among the first OIS-y sensor (631) and the second OIS-y sensor (632), may be disposed spaced apart from a virtual line extending the side of the OIS-y magnet (610).

Referring to FIG. 5, the OIS carrier (310) can be driven in the x-axis direction due to the electromagnetic interaction between the OIS-y magnet (610) and the OIS-y coil (620). Due to the electromagnetic interaction between the OIS-y magnet (610) and the OIS-y coil (620), the OIS carrier (310) can move closer to or farther away from the OIS-y coil (620) in the x-axis direction. At this time, the gap between the OIS carrier (310) and the OIS-y coil (620) in the y-axis direction can be maintained at the same distance.

At a position where the OIS carrier (310) has moved maximally in the x-axis direction, either the first OIS-x sensor (531) or the second OIS-x sensor (532) may overlap with the OIS-x magnet (510) in the y-axis direction, while the other may not overlap with the OIS-x magnet (510) in the y-axis direction. When the OIS carrier (310) is at its maximum position in the x-axis direction, the first OIS-x sensor (531) may overlap with the OIS-x magnet (510) in the y-axis direction, and the second OIS-x sensor (532) may not overlap with the OIS-x magnet (510) in the y-axis direction. When the OIS carrier (310) is at its maximum position in the-x-axis direction, the second OIS-x sensor (532) may not overlap with the OIS-x magnet (510) in the y-axis direction, and the first OIS-x sensor (531) may overlap with the OIS-x magnet (510) in the y-axis direction.

At a position where the OIS carrier (310) has moved maximally in the x-axis direction, a virtual line extending the side of the sensor that does not overlap with the OIS-x magnet (510) in the y-axis direction among the first OIS-x sensor (531) and the second OIS-x sensor (532) may be disposed spaced apart from a virtual line extending the side of the OIS-x magnet (510) (g).

The position where the OIS carrier (310) moves maximally in the x-axis or y-axis direction may vary depending on the distance of the OIS carrier (310)'s driving stroke. The distance of the OIS carrier (310)'s driving stroke may vary depending on the size of the image sensor (60). As the size of the image sensor (60) increases, the size of the OIS carrier (310)'s driving stroke may also increase.

Through this, even if the length of the driving stroke of the OIS carrier (310) increases, the two sensors disposed in each driving axis direction always overlap with the OIS magnet in a direction perpendicular to each driving axis at a position where the OIS carrier (310) has moved maximally in each driving axis direction, thereby enabling precise detection of the movement of the OIS magnet. As a result, the correction angle can be increased compared to when only one sensor is disposed.

Below, the OIS-x coil and OIS-y coil constituting the hand shake correction {Optical Image Stabilization (OIS)} driving unit of the lens driving device according to other embodiments of the present invention will be described with reference to FIGS. 6 to 8. Descriptions overlapping with those described with reference to FIGS. 3 to 5 are omitted.

In another embodiment of the present invention, the OIS-x coil (520) and the OIS-x sensor (530) may be disposed on a single substrate, and the OIS-y coil (620) and the OIS-y sensor (630) may be disposed on a different substrate. The “OIS-x coil (520) and OIS-x sensor (530)” and “OIS-y coil (620) and OIS-y sensor (630)” may be disposed on different substrates adjacent to each other. For example, the first substrate (121) and the second substrate (122) may be disposed adjacent to each other, “OIS-x coil (520) and OIS-x sensor (530)” may be disposed on the first substrate (121), and “OIS-y coil (620) and OIS-y sensor (630)” may be disposed on the second substrate (122). The first substrate (121) and the second substrate (122) may be disposed vertically relative to each other. The “OIS-x coil (520) and OIS-x sensor (530)” may be disposed facing the OIS-x magnet (510). The “OIS-y coil (620) and OIS-y sensor (630)” may be disposed to face the OIS-y magnet (610). The OIS-x coil (520) and OIS-y coil (620) may be formed in a ring shape. The OIS-x coil (520) may include a first OIS-x coil (521) and a second OIS-x coil (522) disposed in a spaced-apart manner. The first OIS-x coil (521) and the second OIS-x coil (522) may be formed with the same size. The OIS-y coil (620) may include a first OIS-y coil (621) and a second OIS-y coil (622) disposed in spaced-apart positions. The first OIS-y coil (621) and the second OIS-y coil (622) may be formed with the same size.

The OIS-x sensor (530) may be disposed inside a ring of the OIS-x coil (520). The OIS-x sensor (530) may be disposed in a hole of the OIS-x coil (520). The OIS-x sensor (530) may include a first OIS-x sensor (531) and a second OIS-x sensor (532) disposed within the first OIS-x coil (521) and the second OIS-x coil (522), respectively. The first OIS-x sensor (531) and the second OIS-x sensor (532) may be disposed at the center portion inside the ring of the first OIS-x coil (521) and the second OIS-x coil (522), respectively. The center portions of the first OIS-x coil (521) and the second OIS-x coil (522) may be the same as the center portions of the first OIS-x sensor (531) and the second OIS-x sensor (532). The length of the OIS-x magnet (510) in the x-axis direction may be shorter than the length of the x-axis direction from the first end (or stage or step) of the first OIS-x coil (521) to the second end of the second OIS-x coil (522). The first end of the first OIS-x coil (521) may face the corner of the substrate, and the second end on the opposite side of the first end may face the second OIS-x coil (522). The first end of the second OIS-x coil (522) may face the second OIS-x coil (522), and the second end on the opposite side of the first end may face the corner of the substrate.

The length of the OIS-x magnet (510) in the x-axis direction may be longer than the distance between the first OIS-x sensor (531) and the second OIS-x sensor (532). The first end of the first OIS-x sensor (531) may face the inner wall of the first end side of the first OIS-x coil (521), and the second end on the opposite side of the first end may face the inner wall of the second end side of the first OIS-x coil (521). The first end of the second OIS-x sensor (532) may face the inner wall of the first end side of the second OIS-x coil (522), and the second end on the opposite side of the first end may face the inner wall of the second end side of the second OIS-x coil (522). The length of the OIS-x magnet (510) in the x-axis direction may be longer than the distance between the first end of the first OIS-x sensor (531) and the second end of the second OIS-x sensor (532). The length of the OIS-x magnet (510) in the x-axis direction may be longer than the distance between the second end of the first OIS-x sensor (531) and the first end of the second OIS-x sensor (532). The OIS-y sensor (630) may be disposed within the ring of the OIS-y coil (620). The OIS-y sensor (630) may be disposed within the hole of the OIS-y coil (620). The OIS-y sensor (630) may include a first OIS-y sensor (631) and a second OIS-y sensor (632) disposed within the first OIS-y coil (621) and the second OIS-y coil (622), respectively. The first OIS-y sensor (631) and the second OIS-y sensor (632) may be disposed at the center portion inside the ring of the first OIS-y coil (621) and the second OIS-y coil (622), respectively. The center portions of the first OIS-y coil (621) and the second OIS-y coil (622) may be the same as the center portions of the first OIS-y sensor (631) and the second OIS-y sensor (632).

The length of the OIS-y magnet (610) in the y-axis direction may be shorter than the length of the y-axis direction from the first end of the first OIS-y coil (621) to the second end of the second OIS-y coil (622). The first end of the first OIS-y coil (621) may face the corner of the substrate, and the second end on the opposite side of the first end may face the second OIS-y coil (622). The first end of the second OIS-y coil (622) may face the first OIS-y coil (621), and the second end on the opposite side of the first end may face the corner of the substrate. The length of the y-axis direction of the OIS-y magnet (610) may be longer than the distance between the first OIS-y sensor (631) and the second OIS-y sensor (632). The first end of the first OIS-y sensor (631) may face the inner wall of the first end side of the first OIS-y coil (621), and the second end on the opposite side of the first end may face the inner wall of the second end side of the first OIS-y coil (621). The first end of the second OIS-y sensor (632) may face the inner wall of the first end side of the second OIS-y coil (622), and the second end on the opposite side of the first end may face the inner wall of the second end side of the second OIS-y coil (622). The length of the OIS-y magnet (610) in the y-axis direction may be longer than the distance between the first end of the first OIS-y sensor (631) and the second end of the second OIS-y sensor (632). The length of the OIS-y magnet (610) in the y-axis direction may be longer than the distance between the second end of the first OIS-y sensor (631) and the first end of the second OIS-y sensor (632).

The first OIS-x sensor (531) and the second OIS-x sensor (532) may overlap with the OIS-x magnet (510) disposed on the OIS carrier (310) in the y-axis direction. At an initial position where the OIS carrier (310) is stationary, the first OIS-x sensor (531) and the second OIS-x sensor (532) may overlap with the OIS-x magnet (510) in the y-axis direction. The initial position may refer to the position of the OIS carrier (310) when no driving current is applied to the coil. The initial position may refer to the position of the OIS carrier (310) when it has not moved. When the OIS carrier (310) has moved, the OIS-x magnet (510) may overlap with at least one of the first OIS-x sensor (531) and the second OIS-x sensor (532) in the y-axis direction.

Referring to FIG. 7, the OIS carrier (310) may be driven in the x-axis direction due to electromagnetic interaction with at least one of the OIS-x magnet (510) and the first OIS-x coil (521) and the second OIS-x coil (522). Through electromagnetic interaction with at least one of the OIS-x magnet (510) and the first OIS-x coil (521) and the second OIS-x coil (522), the OIS carrier (310) can move in the x-axis direction, such that the distance between the OIS carrier (310) and the first OIS-y coil (621) and the second OIS-y coil (622) can increase or decrease. At this time, the gap between the OIS carrier (310) and the first OIS-x coil (521) and the second OIS-x coil (522) in the y-axis direction can be maintained at the same distance.

At the position where the OIS carrier (310) has moved maximally in the x-axis direction, either the first OIS-x sensor (531) or the second OIS-x sensor (532) may overlap with the OIS-x magnet (510) in the y-axis direction, and the other may not overlap with the OIS-x magnet (510) in the y-axis direction. When the OIS carrier (310) is at its maximum position in the −x-axis direction, the first OIS-x sensor (531) may overlap with the OIS-x magnet (510) in the y-axis direction, and the second OIS-x sensor (532) may not overlap with the OIS-x magnet (510) in the y-axis direction. When the OIS carrier (310) is at its maximum position in the +x-axis direction, the first OIS-x sensor (531) may not overlap with the OIS-x magnet (510) in the y-axis direction, and the second OIS-x sensor (532) may overlap with the OIS-x magnet (510) in the y-axis direction. At the position where the OIS carrier (310) has moved maximally in the x-axis direction, a virtual line extending the side of the sensor that does not overlap with the OIS-x magnet (510) in the y-axis direction among the first OIS-x sensor (531) and the second OIS-x sensor (532) may be disposed spaced apart from a virtual line extending the side of the OIS-x magnet (510) (g).

Referring to FIG. 8, the OIS carrier (310) can be driven in the y-axis direction by electromagnetic interaction with at least one of the OIS-x magnet (510) and the first OIS-x coil (521) and the second OIS-x coil (522).

The OIS carrier (310) may be closer to or farther away in distance from the first OIS-x coil (521) and the second OIS-x coil (522) in the y-axis direction due to electromagnetic interaction with at least one of the OIS-x magnet (510), the first OIS-x coil (521), and the second OIS-x coil (522).

At this time, the gap between the OIS carrier (310) and the first OIS-y coil (621) and the second OIS-y coil (622) in the x-axis direction can be maintained the same.

At a position where the OIS carrier (310) has moved maximally in the y-axis direction, either the first OIS-y sensor (631) or the second OIS-y sensor (632) may overlap with the OIS-y magnet (610) in the x-axis direction, while the other may not overlap with the OIS-y magnet (610) in the x-axis direction. When the OIS carrier (310) is at its maximum position in the −y-axis direction, the first OIS-y sensor (631) may overlap with the OIS-y magnet (610) in the x-axis direction, and the second OIS-y sensor (632) may not overlap with the OIS-y magnet (610) in the x-axis direction. When the OIS carrier (310) is maximally moved in the y-axis direction, the first OIS-y sensor (631) may not overlap with the OIS-y magnet (610) in the x-axis direction, and the second OIS-y sensor (632) may overlap with the OIS-y magnet (610) in the x-axis direction.

At a position where the OIS carrier (310) has moved maximally in the y-axis direction, a virtual line extending the side of the sensor that does not overlap with the OIS-y magnet (610) in the x-axis direction from the OIS-y magnet (610) and the second OIS-y sensor (631) may be disposed spaced apart from a virtual line extending the side of the OIS-y magnet (610).

The first OIS-y sensor (631) and the second OIS-y sensor (632) may overlap with the OIS-y magnet (610) disposed on the OIS carrier (310) in the x-axis direction. At an initial position where the OIS carrier (310) is stationary, the first OIS-y sensor (631) and the second OIS-y sensor (632) may overlap with the OIS-y magnet (610) in the x-axis direction. The initial position may refer to the position of the OIS carrier (310) when no driving current is applied to the coil. The initial position may refer to the position of the OIS carrier (310) when it has not moved. When the OIS carrier (310) has moved, the OIS-y magnet (610) may overlap with at least one of the first OIS-y sensor (631) and the second OIS-y sensor (632) in the x-axis direction.

Referring to FIG. 7, the OIS carrier (310) can be driven in the y-axis direction by electromagnetic interaction with at least one of the OIS-y magnet (610) and the first OIS-y coil (621) and the second OIS-y coil (622).

The OIS Carrier (310) can move closer to or farther away from the first OIS-x Coil (521) and the second OIS-x Coil (522) in the y-axis direction by electromagnetic interaction with at least one of the OIS-y magnet (610) and the first OIS-y coil (621) and the second OIS-y coil (622). At this time, the gap between the OIS carrier (310) and the first OIS-y coil (621) and the second OIS-y coil (622) in the x-axis direction may remain the same.

At a position where the OIS carrier (310) has moved maximally in the y-axis direction, either the first OIS-y sensor (631) or the second OIS-y sensor (632) may overlap with the OIS-y magnet (610) in the x-axis direction, and the other may not overlap with the OIS-y magnet (610) in the x-axis direction. When the OIS carrier (310) is at its maximum position in the −y-axis direction, the first OIS-y sensor (631) may overlap with the OIS-y magnet (610) in the x-axis direction, and the second OIS-y sensor (632) may not overlap with the OIS-y magnet (610) in the x-axis direction. When the OIS carrier (310) is at its maximum position in the +y-axis direction, the first OIS-y sensor (631) may not overlap with the OIS-y magnet (610) in the x-axis direction, and the second OIS-y sensor (632) may overlap with the OIS-y magnet (610) in the x-axis direction.

At a position where the OIS carrier (310) has moved maximally in the y-axis direction, a virtual line extending the side of the sensor that does not overlap with the OIS-y magnet (610) in the x-axis direction among the first OIS-y sensor (631) and the second OIS-y sensor (632) may be disposed spaced apart from a virtual line extending the side of the OIS-y magnet (610).

Referring to FIG. 8, the OIS carrier (310) can be driven in the x-axis direction by electromagnetic interaction with at least one of the OIS-y magnet (610) and the first OIS-y coil (621) and the second OIS-y coil (622). The OIS carrier (310) may be closer or farther apart in distance from the first OIS-y coil (621) and the second OIS-y coil (622) in the x-axis direction due to electromagnetic interaction with at least one of the OIS-y magnet (610) and the first OIS-y coil (621) and the second OIS-y coil (622). At this time, the gap between the OIS carrier (310) and the first OIS-x coil (521) and the second OIS-x coil (522) in the y-axis direction can be maintained at the same distance.

At a position where the OIS carrier (310) has moved maximally in the x-axis direction, either the first OIS-x sensor (531) or the second OIS-x sensor (532) may overlap with the OIS-x magnet (510) in the y-axis direction, and the other may not overlap with the OIS-x magnet (510) in the y-axis direction. When the OIS carrier (310) is at its maximum position in the −x-axis direction, the first OIS-x sensor (531) may overlap with the OIS-x magnet (510) in the y-axis direction, and the second OIS-x sensor (532) may not overlap with the OIS-x magnet (510) in the y-axis direction. When the OIS carrier (310) is at its maximum position in the x-axis direction, the first OIS-x sensor (531) may not overlap with the OIS-x magnet (510) in the y-axis direction, and the second OIS-x sensor (532) may overlap with the OIS-x magnet (510) in the y-axis direction.

At a position where the OIS carrier (310) has moved maximally in the x-axis direction, a virtual line extending the side of sensor not overlapping with the first OIS-x sensor (531) and the second OIS-x sensor(532) may be disposed spaced apart from a virtual line extending the side of the OIS-x magnet (510)(g).

Hereinafter, the camera device according to the present embodiment will be described with reference to the drawings.

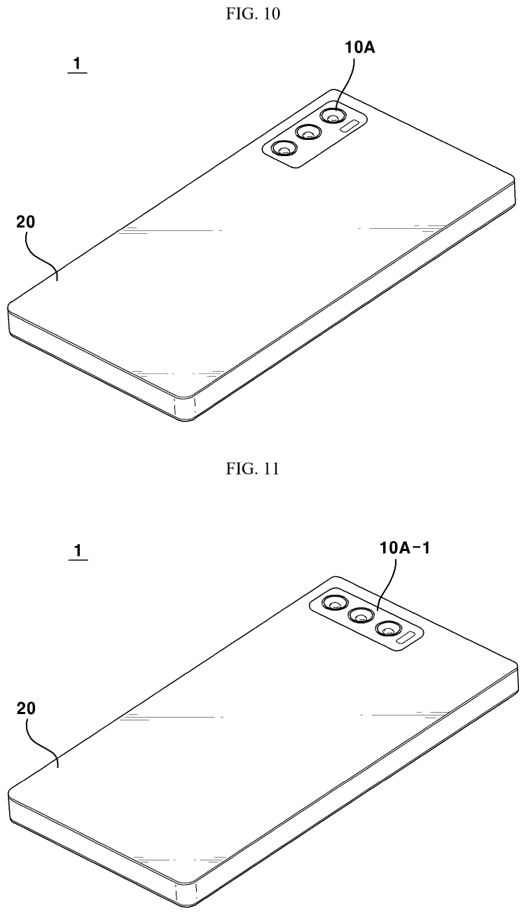

FIG. 10 is an exploded perspective view of a camera device according to the present embodiment.

The camera device (10A) may include a camera module.

The camera device (10A) may include a lens module (20). The lens module (20) may include at least one lens. The lens may be disposed at a location corresponding to the image sensor (60). The lens module (20) may include a lens and a barrel. The lens module (20) may be coupled to an OIS carrier (310) of the lens driving device (10). The lens module (20) may be coupled to the OIS carrier (310) by screw coupling and/or adhesive. The lens module (20) may move integrally with the OIS carrier (310).

The camera device (10A) may include a filter (30). The filter (30) may serve to block light of a specific frequency band from passing through the lens module (20) and entering an image sensor (60). The filter (30) may be disposed parallel to the x-y plane. The filter (30) may be disposed between the lens module (20) and the image sensor (60). The filter (30) may be disposed on a sensor base (40). As a modified alternative embodiment, the filter (30) may be disposed on the base (110). The filter (30) may include an infrared filter. The infrared filter may block light in the infrared region from entering the image sensor (60).

The camera device (10A) may include a sensor base (40). The sensor base (40) may be disposed between the lens driving device (10) and a printed circuit board (50). The sensor base (40) may include a protruder (41) on which the filter (30) is disposed. An opening may be formed in the portion of the sensor base (40) where the filter (30) is disposed to allow light passing through the filter (30) to enter the image sensor (60). An adhesive member may be used to bond or adhere to the base (110) of the lens driving device (10) to the sensor base (40). The adhesive member may further serve to prevent foreign matter from entering the interior of the lens driving device (10). The adhesive member may include one or more of epoxy, thermosetting adhesive, and ultraviolet-curable adhesive.

The camera device (10A) may include a printed circuit board (PCB) (50). The printed circuit board (PCB) (50) may be a substrate or a circuit board. The lens driving device (10) may be disposed on the printed circuit board (PCB) (50). A sensor base (40) may be disposed between the printed circuit board (PCB) (50) and the lens driving device (10). The printed circuit board (50) may be electrically connected to the lens driving device (10). The printed circuit board (50) may include an image sensor (60). The printed circuit board (50) may also include various circuits, components, and control units to convert images formed on the image sensor (60) into electrical signals and transmit them to an external device.

The camera device (10A) may include an image sensor (60). The image sensor (60) may be configured such that light passing through the lens and filter (30) is incident and an image is formed. The image sensor (60) may be mounted on a printed circuit board (50). The image sensor (60) may be electrically connected to the printed circuit board (50). For example, the image sensor (60) may be bonded to the printed circuit board (50) using surface mounting technology (SMT). In another example, the image sensor (60) may be bonded to the printed circuit board (50) using flip chip technology. The image sensor (60) may be disposed such that its optical axis aligns with the lens's optical axis. In other words, the optical axis of the image sensor (60) and the optical axis of the lens may be aligned. The image sensor (60) can convert light incident on the effective image area of the image sensor (60) into an electrical signal. The image sensor (60) may be a CCD (charge-coupled device), MOS (metal oxide semiconductor), CPD, or CID.

The camera device (10A) may include a motion sensor (70). The motion sensor (70) may be mounted on the printed circuit board (50). The motion sensor (70) may be electrically connected to the control unit (80) through the circuit patterns provided on the printed circuit board (50). The motion sensor (70) may output rotational angular velocity information based on the movement of the camera device (10A). The motion sensor (70) may include a two-axis or three-axis gyro sensor (Gyro Sensor) or an angular velocity sensor.

The camera device (10A) may include a control unit (80). The control unit (80) may be disposed on the printed circuit board (50). The control unit (80) may be electrically connected to a coil (330) of the lens driving device (10). The control unit (80) can individually control the direction, magnitude, and amplitude of the current supplied to the coil (330). The control unit (80) can control the lens driving device (10) to perform auto-focusing and/or image stabilization functions. Furthermore, the control unit (80) can perform autofocus feedback control and/or image stabilization feedback control for the lens driving device (10).

The camera device (10A) may include a connector (90). The connector (90) may be electrically connected to the printed circuit board (50). The connector (90) may include a port for electrically connecting to an external device.

The optical instrument according to the present embodiment will now be described with reference to the drawings.

FIG. 10 is a perspective view of the optical instrument according to the present embodiment, and FIG. 11 is a perspective view of the optical instrument according to a modified example.

An optical instrument (1) may include any one or more of the following: mobile phones, cell phones, mobile terminals, mobile devices, smartphones, smart pads, portable smart devices, digital cameras, laptop computers, digital broadcasting terminals, PDAs (Personal Digital Assistants), PMPs (Portable Multimedia Players), and navigation devices. The optical instrument (1) may include any device used for capturing images or photographs.

The optical instrument (1) may include a main body (20). The optical instrument (1) may include a camera device (10A). The camera device (10A) may be disposed in the main body (20). The camera device (10A) may capture an object. The optical instrument (1) may include a display. The display may be disposed on the main body (20). The display may output one or more of the images and videos captured by the camera device (10A). The display may be disposed on the first surface of the main body (20). The camera device (10A) may be disposed on one or more of the first surface and the second surface opposite the first surface of the main body (20). As shown in FIG. 10, the camera device (10A) may include a triple camera disposed in a vertical direction. As shown in FIG. 11, a camera device (10A-1) may include a triple camera disposed in a horizontal direction.

Those skilled in the art related to the field of the present embodiment will understand that the present invention may be implemented in modified forms without departing from the essential characteristics of the above description. Therefore, the disclosed methods should be considered from an explanatory perspective rather than a limited perspective. The scope of the present invention is not limited to the above description, but is defined by the scope of the appended claims, and all differences within the scope of the appended claims shall be interpreted as falling within the scope of the present invention.

1. A lens driving device comprising: a fixed unit;
a first moving unit disposed on the fixed unit;
a second moving unit disposed within the first moving unit;
a first driving unit configured to move the first moving unit in the optical axis direction; and
a second driving unit configured to move the second moving unit in a first direction perpendicular to the optical axis direction,
wherein the second driving unit comprises a second magnet disposed on the second moving unit; and a second coil and a second sensor disposed on the fixed unit,
wherein the second sensor comprises two sensors spaced apart in the first direction within the second coil,
wherein at least one of the two sensors overlaps the second magnet in a second direction perpendicular to the optical axis direction and the first direction, and
wherein when the second moving unit is moved to its maximum position in the first direction, one of the second sensors overlaps with the second magnet in the second direction, while the other second sensor does not overlap with the second magnet in the second direction.

2. The lens driving device of claim 1, wherein a length of the second magnet is longer than the distance between the two sensors of the second sensor.

3. (canceled)

4. The lens driving device of claim 1, wherein the second coil comprises two coils spaced apart from each other in the first direction, and the second sensor includes two sensors disposed inside each of the two coils.

5. The lens driving device of claim 1, wherein a length of the second magnet in the first direction is shorter than a length of the second coil in the first direction.

6. The lens driving device of claim 1, comprising:
a substrate disposed on a side of the fixed unit,
wherein the second coil and the second sensor are disposed on the substrate, and
wherein the second coil and the second sensor overlap with the substrate in the second direction.

7. The lens driving device of claim 1, comprising:
a third driving unit configured to move the second moving unit in the second direction,
wherein the third driving unit includes a third magnet disposed on the second moving unit, a third coil and a third sensor disposed on the fixed unit,
wherein the third sensor comprises two sensors disposed in the third coil and spaced apart in the second direction, and
wherein at least one of the two sensors of the third sensor overlaps with the third magnet in the first direction.

8. A lens driving device comprising:
a fixed unit;
a first moving unit disposed on the fixed unit;
a second moving unit disposed within the first moving unit;
a first driving unit configured to move the first moving unit in the optical axis direction; and
a second driving unit configured to move the second moving unit in a first direction perpendicular to the optical axis direction,
wherein the second driving unit comprises a second magnet and a third magnet disposed on the second moving unit, a second coil and a third coil disposed on the fixed unit, a second sensor disposed within the second coil, and a third sensor disposed within the third coil,
wherein the second sensor comprises two second sensors spaced apart within the second coil, and the third sensor comprises two third sensors spaced apart within the third coil, and
wherein when the second moving unit is moved to its maximum position in the first direction, one of the second sensors overlaps with the second magnet in the second direction, while the other second sensor does not overlap with the second magnet in the second direction.

9. The lens driving device of claim 8, wherein the two second sensors are spaced apart in the first direction,
wherein the two third sensors are spaced apart in the second direction, and
wherein the second moving unit is moved in the second direction by the second magnet and the second coil and is moved in the first direction by the third magnet and the third coil.

10. A lens driving device comprising:
a fixed unit;
a first moving unit disposed on the fixed unit;
a second moving unit disposed within the first moving unit;
a first driving unit configured to move the first moving part in the optical axis direction; and
a second driving unit configured to move the second moving unit in a direction perpendicular to the optical axis direction,
wherein the second driving unit comprises a second magnet disposed on the second moving unit, a second coil disposed on the fixed unit, and a second sensor,
wherein the second coil comprises an inner surface and an outer surface,
wherein the second sensor comprises two second sensors spaced apart from the inner surface of the second coil, and
wherein a shortest distance between the two second sensors is greater than a shortest distance between at least one of the two second sensors and the inner surface of the second coil.

11. The lens driving device of claim 1, wherein the second sensor comprises two second sensors disposed inside each of the two coils.

12. The lens driving device of claim 8, wherein when the second moving unit is moved to its maximum position in a second direction, one of the second sensors overlaps with the second magnet in the second direction, while the other second sensor does not overlap with the second magnet in the second direction, and
wherein the second direction is a direction perpendicular to the optical axis direction and the first direction.

13. The lens driving device of claim 9, wherein a length of the second magnet is longer than the distance between the two second sensors.

14. The lens driving device of claim 9, wherein a length of the third magnet is longer than the distance between the two third sensors.

15. The lens driving device of claim 8, wherein the second coil comprises an inner surface and an outer surface,
wherein the second sensor comprises two second sensors spaced apart from the inner surface of the second coil, and
wherein a shortest distance between the two second sensors is greater than a shortest distance between at least one of the two second sensors and the inner surface of the second coil.

16. The lens driving device of claim 8, wherein the third coil comprises an inner surface and an outer surface,
wherein the third sensor comprises two third sensors spaced apart from the inner surface of the third coil, and
wherein a shortest distance between the two third sensors is greater than a shortest distance between at least one of the two third sensors and the inner surface of the third coil.

17. The lens driving device of claim 10, comprising:
a third driving unit configured to move the second moving unit in the second direction,
wherein the third driving unit comprises a third magnet disposed on the second moving unit, a third coil and a third sensor disposed on the fixed unit,
wherein the third sensor comprises two third sensors disposed in the third coil and spaced apart in the second direction, and
wherein at least one of the two third sensors overlaps with the third magnet in the first direction.

18. The lens driving device of claim 10, wherein when the second moving unit is moved to its maximum position in the first direction, one of the second sensors overlaps with the second magnet in the second direction, while the other second sensor does not overlap with the second magnet in the second direction.

19. The lens driving device of claim 10, wherein a length of the second magnet is longer than the distance between the two second sensors.

20. The lens driving device of claim 10, wherein a length of the second magnet in the first direction is shorter than a length of the second coil in the first direction.

21. The lens driving device of claim 10, wherein when the second moving unit is moved to its maximum position in the first direction, one of the second sensors overlaps with the second magnet in the second direction, while the other second sensor does not overlap with the second magnet in the second direction.
